(19) United States
(12) Patent Application Publication
(10) Pub. No.: US 2008/0202920 A1
(43) Pub. Date: Aug. 28, 2008

(54) Ion Milling system and ion milling method

(75) Inventors: Toru Iwaya, Hitachinaka (JP); Hirobumi Muto, Hitachinaka (JP); Sakae Kobori, Shirosato (JP)

Correspondence Address: MCDERMOTT WILL & EMERY LLP, 600 13TH STREET, N.W., WASHINGTON, DC, 20005-3096, US

(73) Assignee: HITACHI HIGH-TECHNOLOGIES CORPORATION

(21) Appl. No.: 12/071,543

(22) Filed: Feb. 22, 2008

(30) Foreign Application Priority Data
Feb. 22, 2007 (JP) 2007-042225

(51) Int. Cl. C23C 14/00

(52) U.S. Cl. 204/192.34

(57) ABSTRACT

In an ion milling system and an ion milling method for making unnecessary the effort of resetting a sample in a sample stage mechanism whenever a machining region is changed, the system includes an ion gun that generates an ion beam with which a sample is to be irradiated, a sample chamber within which the sample to be subjected to irradiation processing by the ion beam is put, an exhaust that evacuates air in order to maintain vacuum in the sample chamber, a gas injection mechanism that injects ion-generating gas, and a sample stage mechanism in which the sample is placed and which rotates with the sample set thereon. The sample stage mechanism has a rotary table that rotates with the sample set thereon, a rotating mechanism that drives the rotary table, an eccentric mechanism capable of eccentrically adjusting a positional relationship between a rotation center axis of the rotary table and a centerline of the ion beam, and a sample position adjusting mechanism capable of eccentrically adjusting a positional relationship between a centerline of the sample set on the sample stage and the rotation center axis of the rotary table.

### BACKGROUND OF THE INVENTION

1. Field of the Invention

The present invention relates to an ion milling system and an ion milling method for preparing a sample to be observed by a scan electron microscope (SEM), a transmission electron microscope (TEM), etc.

2. Description of Related Art

An ion milling system is an apparatus for polishing a surface or cross-section of metal, glass, ceramic, or the like, such as by irradiating the surface or cross-section with an argon ion beam, and is suitable as a pretreatment system for observing the surface or cross-section of a sample with an electron microscope.

In the cross-section observation of the sample by the electron microscope, conventionally, after the vicinity of a portion to be observed is cut using a diamond cutter, a fret saw, etc., a cutting surface is polished mechanically, the sample is then attached to a sample stage for the electron microscope, and the image of the cutting surface is observed. In the case of mechanical polishing, for example, a polymeric material or a soft sample like aluminum, has a problem in that a surface to be observed is crushed or deep scratches remain due to particles of abrasive. Moreover, a hard sample such as glass or ceramic has a problem in that polishing is difficult, and a composite material in which a soft material and a hard material are laminated has a problem in that surface section machining is very difficult.

On the other hand, in the case of ion milling, even the soft material can be machined without crushing of the shape of the surface thereof, and the hard sample or composite material can be polished. The ion milling has also the effect that a specular section can be easily obtained. It is reported in JP-A-3-36285 that a flat machining surface having a diameter of about 5 mm is obtained by putting a sample on a rotary body, and by milling the sample with the rotation center axis of the rotary body and a sample surface irradiation position of the center of an ion beam being shifted by a predetermined distance.

In the above conventional apparatus, when a sample is set on the sample stage mechanism, the machining region of the sample is always the same, and thus, the sample must be detached from the sample stage mechanism for milling other machining regions. Further, since a machining spot of the sample had to be set near the center of a resin embedding container when resin embedding or the like of the sample that is a pretreatment technique is performed, careful operation is required.

### SUMMARY OF THE INVENTION

In view of such problems, a object of the invention is to provide an ion milling system and an ion milling method that make unnecessary the effort of resetting a sample in a sample stage mechanism whenever a machining region is changed.

In order to achieve the above object, according to the invention, an ion milling system includes: an ion gun that generates an ion beam with which a sample is to be irradiated; a sample chamber within which the sample to be subjected to irradiation processing by the ion beam is put; an exhaust that evacuates air in order to maintain vacuum in the sample chamber; a gas injection mechanism that injects ion-generating gas; and a sample stage mechanism in which the sample is placed and which rotates with the sample set thereon. Here, the sample stage mechanism has a rotary table that rotates with the sample set thereon, a rotating mechanism that drives the rotary table, an eccentric mechanism capable of eccentrically adjusting a positional relationship between a rotation center axis of the rotary table and a centerline of the ion beam, and a sample position adjusting mechanism capable of eccentrically adjusting a positional relationship between a centerline of the sample set on the sample stage, and a rotation center axis of the rotary table.

Further, the invention provides an ion milling method using an ion milling system including: an ion gun that generates an ion beam with which a sample is to be irradiated; a sample chamber within which the sample to be subjected to irradiation processing by the ion beam is put; an exhaust that evacuates air in order to maintain vacuum in the sample chamber; a gas injection mechanism that injects ion-generating gas; and a sample stage mechanism on which the sample is placed and which rotates with the sample set thereon. The sample stage mechanism has a rotary table that rotates with the sample set thereon, and a rotating mechanism that drives the rotary table. Here, when the sample is irradiated with the ion beam in a state where a rotation center of the rotary table and a centerline of the ion beam are shifted and rotated, the centerline of the sample is moved so as to shift respect to the rotation center axis of the rotary table with the rotation center axis of the rotary table being not moved but fixed, thereby machining any regions of the sample.

According to the invention, since positional adjustment between the rotation centers of a sample and a sample stage becomes possible after setting of the sample onto the sample stage, it is possible to provide an ion milling method and an ion milling apparatus capable of selecting any milling regions, and capable of performing milling in a plurality of spots without removing the sample.

Other objects, features and advantages of the invention will become apparent from the following description of the embodiments of the invention taken in conjunction with the accompanying drawings.

### BRIEF DESCRIPTION OF SEVERAL VIEWS OF DRAWINGS

FIG. 1 is a view showing a schematic configuration of an ion milling system according to one embodiment of the invention;

FIG. 2 is a view showing a positional relationship in a case where the rotation center is made eccentric from a sample surface irradiation position (in the case of a conventional apparatus);

FIG. 3 is a view showing a milling profile in the above condition (FIG. 2);

FIG. 4 is a view showing a positional relationship in a case where the rotation center is made eccentric from a sample surface irradiation position, and the centerline of the sample is made eccentric from the rotation center (in the case of the apparatus according to the invention); and

FIG. 5 is a view showing a milling profile in the above condition (FIG. 4).

### DETAILED DESCRIPTION OF THE INVENTION

Hereinafter, an embodiment according to the invention will be described with reference to the drawings.

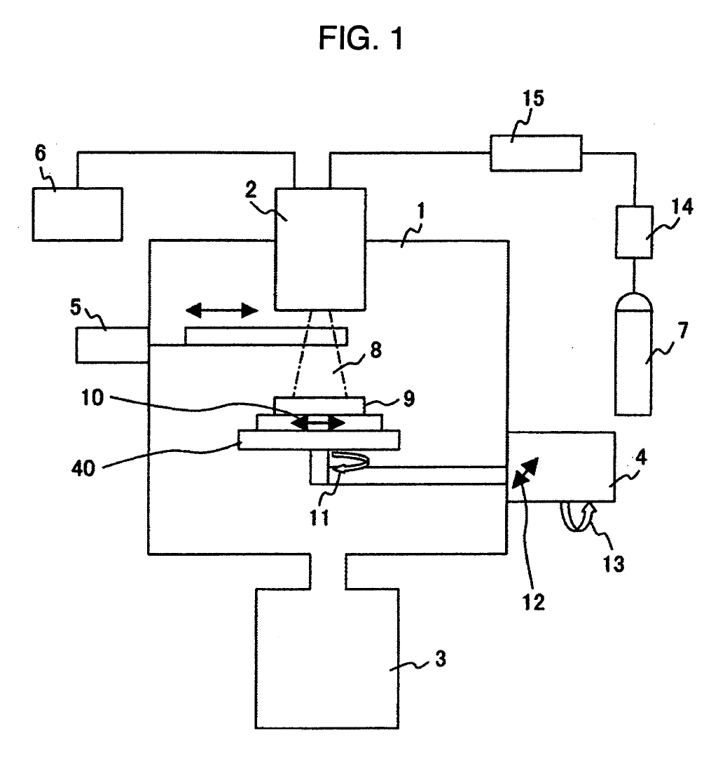

FIG. 1 shows an ion milling system according to an embodiment of the invention, which is mainly composed of a sample chamber 1, an ion gun 2, an exhaust 3, a sample stage mechanism 4, an ionic current measuring device 5, a high-voltage unit 6, and a gas supply source 7. Hereinafter, a case where an argon ion beam is radiated from the ion gun 2 will be described. Accordingly, although an ion beam 8 means the argon ion beam in the following description, this embodiment is not limited to the argon ion beam. Further, although a case where a centerline 18 of a sample 9 and a rotation center axis 17 of a rotary table 40 are coaxial when the sample 9 is set will be described below, this embodiment is not limited to the fact that the centerline 18 of the sample and the rotation center axis 17 of the rotary table 40 are coaxial when the sample is set.

The sample stage mechanism 4 has the rotary table 40, a rotating mechanism 11 that drives the rotary table 40, and an eccentric mechanism 12 that can eccentrically adjust a positional relationship between the rotation center axis 17 of the rotary table 40 and the centerline of the ion beam 8. Moreover, the sample stage mechanism 4 has a sample position adjusting mechanism 10 that can eccentrically adjust the positional relationship between the centerline 18 of the sample 9 set on the sample stage mechanism 4 and the rotation center axis 17 of the rotary table 40, and an angle adjusting mechanism 13 that can optionally adjust the inclined angle of the rotation center axis 17 of the rotary table 40 with respect to the centerline of the ion beam 8.

The inside of the sample chamber 1 is evacuated by the exhaust 3 until the degree of vacuum becomes about 10⁻⁴ to 10⁻³ Pa. Within this sample chamber 1 are provided the ion gun 2 that emits the ion beam 8, the sample position adjusting mechanism 10 on which the sample 9 is set and which adjusts the positional relationship between the sample 9 and the rotation center axis 17 of the rotary table 40, and the rotating mechanism 11 that rotates the sample 9. The eccentric mechanism 12 that shifts the rotation center axis 17 of the rotary table 40 and a sample surface irradiation position 16 of the centerline of the ion beam 8 by an optional distance, the sample stage mechanism 4 having the angle adjusting mechanism 13 that inclines a sample surface with respect to the centerline of the ion beam 8, and the ionic current measuring device 5 that measures the current value of the ion beam 8 are included. Here, the sample 9, the sample position adjusting mechanism 10, and the rotating mechanism 11 can be moved in one direction perpendicular to the centerline of the ion beam 8 by the eccentric mechanism 12. This moving direction may be two directions (front and rear directions or right and left directions). That is, it is possible to secure (shift) an eccentric distance 19 obtained by making the rotation center axis 17 of the rotary table 40 eccentric by an optional distance from the sample surface irradiation position 16 of the centerline of the ion beam 8. Furthermore, by moving the sample position adjusting mechanism 10, the positional relationship between the centerline 18 of the sample 9 and the rotation center axis 17 of the rotary table 40 will be changed.

Argon gas is reduced in pressure to about 0.03 MPa by a pressure-reducing valve 14 from the gas supply source 7 that is a supply source of the argon gas, is then adjusted in flow rate by a flow rate control unit 15, and is supplied to the ion gun 2. The ion gun 2 makes the introduced argon gas ionized by the high-voltage unit 6, and emits the ion beam 8. This ion beam 8 is first radiated onto the ion current measuring device 5 where ion current is measured. Whether the ion current value has become stable is checked, the ionic current measuring device 5 is pulled toward a near side, and the sample is irradiated with the ion beam 8. Further, since the ion gun 2 makes a potential of an accelerating electrode that accelerates ions within the ion gun 2 lower than the potential of the sample, it has a function to prevent charge-up that occurs when the dielectric sample is irradiated with ions. Further, it is also possible to make the potential of the accelerating electrode for accelerating an ion beam negative with respect to the potential of the sample. Moreover, it is also possible to provide an ion beam shielding plate that shields an ion beam between the ion gun and the sample.

The positional relationship between the ion beam 8 and the sample 9, which is adjusted by the ion milling system described in the embodiment of the invention, will be described in comparison with a conventional apparatus in order to make the differences between the conventional apparatus and the ion milling system of this embodiment easily understood.

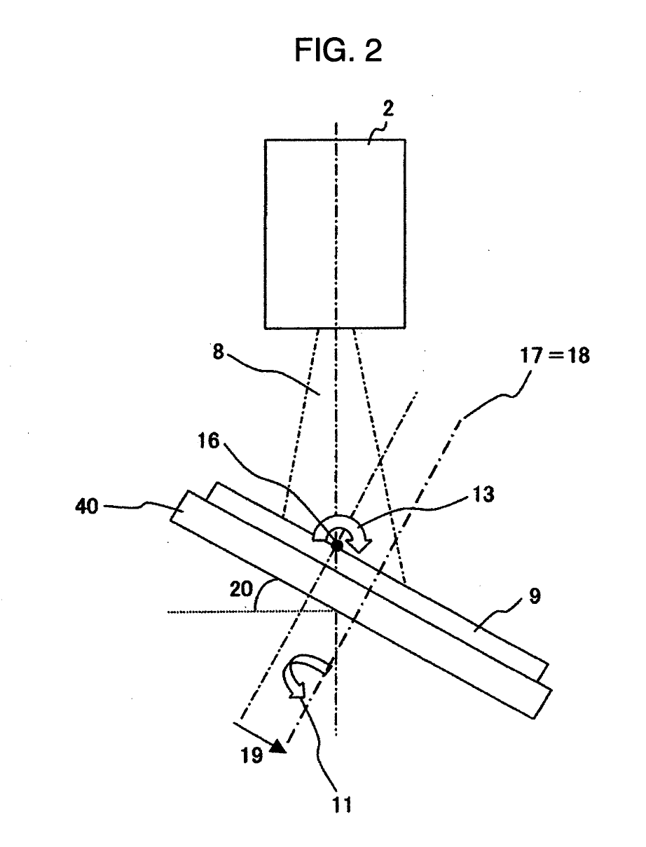

In the conventional apparatus, as shown in FIG. 2, the sample 9 is set with the centerline 18 of the sample 9 aligned with the rotation center axis 17 of the rotary table 40, and the eccentric distance 19 obtained by making the rotation center axis 17 of the rotary table 40 eccentric by D1 from the sample surface irradiation position 16 by the eccentric mechanism 12 is secured. Furthermore, the angle of inclination 20 of the rotary table 40 is adjusted to α degrees by an angle adjusting mechanism 13, and the ion beam 8 is made incident while the rotary table 40 is rotated.

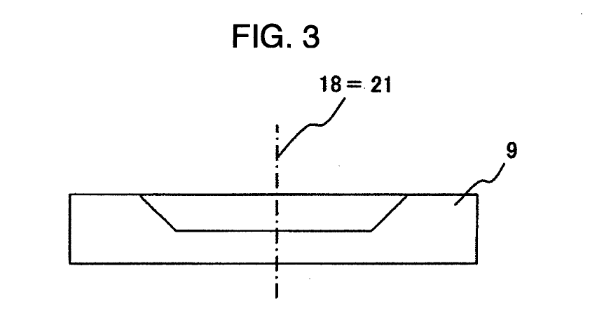

The milling profile (milling shape) of a cross-section at this time is shown in FIG. 3. In this case, the centerline 18 of the sample 9 and a centerline 21 (rotation center axis 17 of the rotary table 40) of the flat milling profile are always coaxial, and milling centered on portions other than the centerline 18 of the sample 9 could not be performed. (Here, when the value of the eccentric distance 19 is set to D1, and the value of the angle of inclination 20 of the rotary table 40 is set to α degrees, it is made a condition that a central portion of the milling profile becomes flat.)

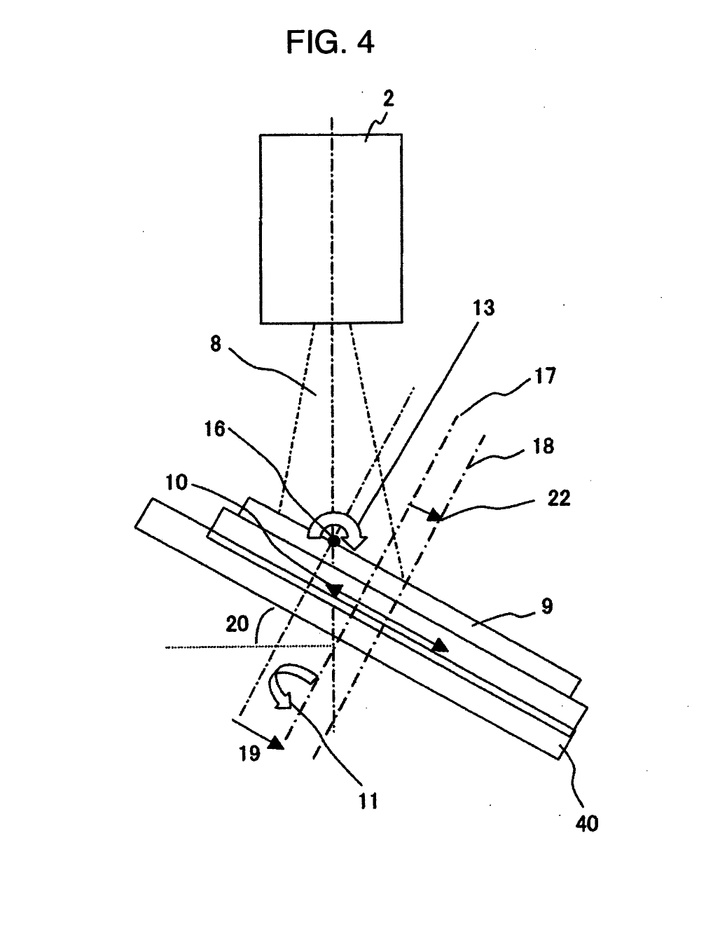

In the ion milling system according to the embodiment of the invention, in addition to the above condition, as shown in FIG. 4, the eccentric distance 22 between the centerline 18 of the sample 9 and the rotation center axis 17 of the rotary table 40 is adjusted to D2 by the sample position adjusting mechanism 10 (an eccentric direction can be freely selected with respect to a sample surface), and the ion beam 8 is made incident while the sample stage 4 is rotated.

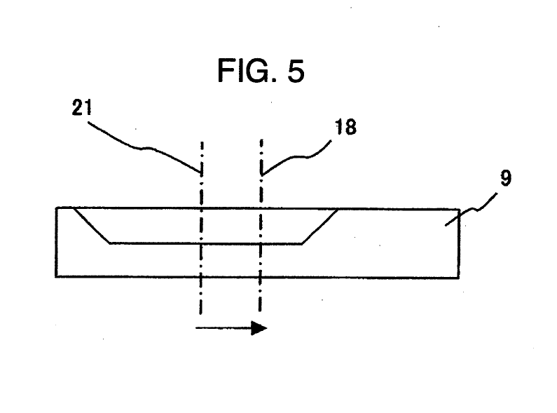

The milling profile of a cross-section at this time is shown in FIG. 5. In this case, the centerline 18 of the sample 9 and the centerline 21 (rotation center axis 17 of the rotary table 40) will shift by D2 that is the value of the eccentric distance 22. By adjusting the value of such D2, regions other than the centerline 18 of the sample 9 can be selected as the centerline 21 of the milling profile.

The following method is performed when milling centered on optional points is performed actually. Since the rotation center axis 17 of the rotary table 40 and the centerline 21 of a milling profile are the same, flat milling centered on optional points can be performed by setting a memory that can confirm the position of the rotation center axis 17 of the rotary table 40 on the eccentric mechanism 12 of the sample stage mechanism 4, and setting the sample 9 on the rotary table 40, and then by making a machining position aligned with the memory by the sample position adjusting mechanism 10.

According to this embodiment, it is possible to provide an ion milling system and an ion milling method, capable of selecting optional milling regions, and performing milling in a plurality of spots without removing a sample.

It should be further understood by those skilled in the art that although the foregoing description has been made on embodiments of the invention, the invention is not limited thereto and various changes and modifications may be made without departing from the spirit of the invention and the scope of the appended claims.

1. An ion milling system comprising:
an ion gun that generates an ion beam with which a sample is to be irradiated;
a sample chamber within which said sample to be subjected to irradiation processing by said ion beam is put;
an exhaust that evacuates air in order to maintain vacuum in said sample chamber;
a gas injection mechanism that injects ion-generating gas; and
a sample stage mechanism on which said sample is placed and which rotates with said sample set thereon,
wherein said sample stage mechanism has a rotary table that rotates with said sample set thereon, a rotating mechanism that drives said rotary table, an eccentric mechanism capable of eccentrically adjusting a positional relationship between a rotation center axis of said rotary table and a centerline of said ion beam, and a sample position adjusting mechanism capable of eccentrically adjusting a positional relationship between a centerline of the sample set on said sample stage and said rotation center axis of said rotary table.

2. The ion milling system according to claim 1, wherein said sample stage mechanism has an angle adjusting mechanism capable of optionally adjusting an inclined angle of the rotation axis center of said rotary table with respect to said centerline of said ion beam.

3. The ion milling system according to claim 1, wherein said system has a function that acquires a position of a milling profile centerline, i.e., the rotation center axis of the rotary table.

4. The ion milling system according to claim 1, wherein an accelerating electrode for accelerating said ion beam has a negative potential with respect to a potential of said sample.

5. The ion milling system according to claim 1, wherein an ion beam shielding plate that shields said ion beam is provided between said ion gun and said sample.

6. The ion milling system according to claim 5, wherein said ion beam shielding plate further has a function to measure a current of said ion beam.

7. An ion milling method using an ion milling system comprising: an ion gun that generates an ion beam with which a sample is to be irradiated; a sample chamber within which said sample to be subjected to irradiation processing by said ion beam is put; an exhaust that evacuates air in order to maintain vacuum in said sample chamber; a gas injection mechanism that injects ion-generating gas; and a sample stage mechanism in which said sample is placed and which rotates with said sample set thereon, said sample stage mechanism having a rotary table that mounts said sample and rotates with said sample set thereon, and a rotating mechanism that drives said rotary table,
wherein, when said sample is irradiated with said ion beam in a state where a rotation center of said rotary table and a centerline of said ion beam are shifted with each other and rotated, a centerline of said sample is eccentrically adjusted with respect to said rotation center axis of said rotary table with said rotation center axis of said rotary table being not moved but fixed, thereby machining optional regions of said sample.

8. The ion milling method according to claim 7, wherein said sample stage mechanism inclines said rotation axis center of said rotary table with respect to said centerline of said ion beam.

9. The ion milling system according to claim 7, wherein a position of a milling profile centerline, i.e., said rotation center axis of said rotary table is acquired.

10. The ion milling method according to claim 7, wherein milling is performed while right rotation and left rotation of said rotary table are alternately repeated.
